(19) United States
(12) Patent Application Publication
(10) Pub. No.: US 2025/0044772 A1
(43) Pub. Date: Feb. 6, 2025

(54) METHODS FOR GENERATING AN INTEGRATED LIST OF EXECUTABLE INSTRUCTIONS USING DISPARATE SOFTWARE PACKAGES AND RELATED SYSTEMS

(71) Applicant: Northrop Grumman Systems Corporation, Falls Church, VA (US)

(72) Inventors: Ian J. Freeman, Layton, UT (US); Barrett B. Milenski, Salt Lake City, UT (US); David Ivankovich, Torrance, CA (US); Sean Harms, Redondo Beach, CA (US); Zachary R. Doyle, St. Augustine, FL (US)

(21) Appl. No.: 18/363,647

(22) Filed: Aug. 1, 2023

(51) Int. Cl. G05B 19/418; G06F 30/10

(52) U.S. Cl. CPC G05B 19/4181; G05B 19/41885; G06F 30/10

(57) ABSTRACT

A method may include providing the design inputs to a first software package and a second software package, receiving one or more first instructions from the first software package and one or more second instructions from the second software package, generating one or more third instructions based, at least in part, on the one or more first instructions or the one or more second instructions, providing the one or more first instructions, the one or more second instructions, and/or the one or more third instructions to the first software package and/or the second software package, receiving a first list of executable instructions and a second list of executable instructions from the first software package and the second software package, respectively, and merging the first list of executable instructions and the second list of executable instructions to generate an integrated list of executable instructions.

### TECHNICAL FIELD

Embodiments of the present disclosure relate generally to systems and methods for merging one or more executable instructions received from independent software packages into an integrated list of executable instructions.

### BACKGROUND

Computerized instructions may enable automatic and precise control of various processes. The computerization of manufacturing has led to an increase in the amount of tasks that may be automatically and accurately performed by motorized machine tools. Numerical control (NC) may enable the automatic control of machine tools used for manufacturing various articles of manufacture. NC instructions may be provided to a motorized tool or a tool platform such that, when executed, the instructions control the movement or positioning of the tool or the platform to allow the tool to manufacture an article. For example, NC instructions may be used in controlling a process of additively manufacturing an article.

### BRIEF SUMMARY

Some embodiments of the present disclosure include a method that may include receiving design inputs for a pre-determined machine-driven process, providing the design inputs to a first software package and a second software package, each of the first software package and the second software package configured to generate a list of executable instructions for performing at least a portion of the pre-determined machine-driven process, receiving one or more first instructions from the first software package and one or more second instructions from the second software package, generating one or more third instructions based, at least in part, on the one or more first instructions or the one or more second instructions, providing the one or more first instructions, the one or more second instructions, and/or the one or more third instructions to the first software package and/or the second software package, receiving a first list of executable instructions and a second list of executable instructions from the first software package and the second software package, respectively, and merging the first list of executable instructions and the second list of executable instructions to generate an integrated list of executable instructions.

Additional embodiments of the present disclosure may include a system including a robotic arm that may include a plurality of machine tools. The system may also include at least one processor and at least one non-transitory computer-readable storage medium storing instructions thereon that, when executed by the at least one processor, cause the system to receive design inputs for a manufacturing an article, provide the design inputs to a first software package and a second software package, each of the first software package and the second software package configured to generate a list of executable instructions configured to perform at least part of a process of manufacturing the article, receive one or more first instructions from the first software package and one or more second instructions from the second software package, generate one or more third instructions based, at least in part, on the one or more first instructions or the one or more second instructions, provide the one or more first instructions, the one or more second instructions, and/or the one or more third instructions to the first software package and/or the second software package, receive a first list of executable instructions and a second list of executable instructions from the first software package and the second software package, respectively, and merge the first list of executable instructions and the second list of executable instructions to generate an integrated list of executable instructions.

Further embodiments of the present disclosure may include a non-transitory computer-readable storage medium storing instructions thereon that, when executed by the at least one processor, perform acts including receiving design inputs for a pre-determined machine-driven process, providing the design inputs to a first software package and a second software package, each of the first software package and the second software package configured to generate a list of executable instructions for performing at least a portion of the pre-determined machine-driven process, receiving one or more first instructions from the first software package and one or more second instructions from the second software package, generating one or more third instructions based, at least in part, on the one or more first instructions or the one or more second instructions, providing the one or more first instructions, the one or more second instructions, and/or the one or more third instructions to the first software package and/or the second software package, receiving a first list of executable instructions and a second list of executable instructions from the first software package and the second software package, respectively, and merging the first list of executable instructions and the second list of executable instructions to generate an integrated list of executable instructions.

### BRIEF DESCRIPTION OF THE SEVERAL VIEWS OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 is a schematic view of an example manufacturing tool system according to one or more embodiments of the present disclosure;

FIGS. 2A-2C illustrate a sequence diagram that a manufacturing tool system can utilize to generate an integrated list of executable instructions in accordance with one or more embodiments;

FIG. 3 is a flowchart illustration of an operation of a manufacturing tool system for processing one or more design inputs according to one or more embodiments of the present disclosure;

FIG. 4 is a flowchart illustration of an operation of a manufacturing tool system for evaluating or manipulating data received from as well as providing data to one or more independent software packages according to one or more embodiments of the present disclosure;

FIG. 5 is a flowchart illustration of an operation of a manufacturing tool system for merging lists of executable instructions according to one or more embodiments of the present disclosure; and

FIG. 6 is a block diagram of circuitry that, in some examples, may be used to implement various functions, operations, acts, processes, and/or methods disclosed herein.

### DETAILED DESCRIPTION

Numeric Control (NC) programming (sometimes referred to as “offline programming”) may involve a process of creating a list of instructions for controlling a machine tool. For example, creating NC instructions may include creating one or more tool paths and various movements and operations of the machine tool to produce or manipulate an article of manufacture. NC programming is often combined with or through the use of process simulation (e.g., simulating the tool path or manufacturing process to verify that the part can be manufactured or machined as intended). NC programming may be used in a variety of manufacturing contexts. For example, NC programming may be used to control a process of additive manufacturing, automated fiber placement, large pellet extrusion, or subtractive manufacturing (e.g., machining), without limitation.

When programming NC instructions for a process, each separate process may be defined using a specialized programming software package (e.g., a computer application) for creating and organizing the instructions. For example, in a process of additive manufacturing, a software package may be used to generate or edit one or more instructions for performing the additive manufacturing process such as generating instructions for a layer-by-layer deposition of materials to form a pre-defined geometric shape. The amount of different manufacturing processes may be vast. For example, additive manufacturing processes may include, for example, stereolithographic processes, powder bed fusion (PBF) processes such as selective laser sintering (SLS), binder jetting, material extrusion (e.g., fused filament fabrication (FFF), directed energy deposition (DED) such as laser metal deposition (LMD)), among other processes. Each different additive manufacturing process may also have a specialized programming software package designed to facilitate the creation of NC instructions for the specialized additive manufacturing process depending on the disparate requirements of each process. Additionally, other software packages may be used to generate a list of instructions for controlling various machining processes to remove materials from a given article (e.g., milling, turning, laser cutting, or water jet cutting, without limitation), for controlling an automated fiber placement process, or a large pellet extrusion process. Each process may require different tools in order to perform the process.

Furthermore, in some cases, a desired article may require one or more different processes (e.g., additive manufacturing, automated fiber placement, subtractive manufacturing, without limitation) to complete an article of manufacture. For example, one software package may generate a list of NC instructions to additively manufacture an article and another software package may then generate a list of instructions to machine or remove parts of the article that was manufactured through additive manufacturing. However, because each different process may require different machine tools in order to perform each process, the NC instructions for each process are typically developed using siloed, independent software packages. For example, an additive manufacturing process may require various tools necessary for additive manufacturing such as an extruder, a feed material, heating implements, etc. Conversely, a subtractive manufacturing process may require lathes, drill presses, grinders, band saws, waterjet apparatus', plasma cutters, etc. Accordingly, multiple processes may require multiple separate tools, which may lead to long manufacturing times for manufacturing the article as the various tools may need to be swapped in or out at various stages of manufacturing.

One approach to manufacturing an article requiring multiple NC manufacturing processes using different tools may involve combining the tools into a single machine and/or motion platform. For example, a robotic arm positioned on a motion platform may include one or more tools for additive manufacturing as well as one or more tools for subtractive manufacturing or automated fiber placement or any other tool for a manufacturing process. However, even if the tools required for multiple manufacturing processes are combined into a single tool such as a robotic arm, each process is typically controlled by a unique set of instructions generated by siloed, offline software packages. These software packages are each typically configured to generate a list of executable NC instructions for completing a single manufacturing process without knowledge of other manufacturing processes that have been or need to be done to the article. Running each process separately may lead to long manufacture times and mitigate the advantage of combining tools into a single machine and/or motion platform. Some approaches to allow for controlling multiple processes using a single machine may involve manually developing all of the needed software needed to generate a single list of executable instructions for multiple manufacturing processes in a single software package. However, NC processes are vastly complex and various standard manufacturing software packages currently available for individual manufacturing processes may have been developed and expanded on over the course of years and sometimes decades. Thus, developing a single software package to perform the same functionality of multiple mature software packages in a single software package may be extremely expensive and time consuming.

Accordingly, in order to avoid the expense and time of developing a single software package for performing multi-format processes, an integration software may be provided to facilitate and coordinate executable instruction generation at independent software packages to create lists of executable instructions that are configured to be merged together by the integration software into a single integrated list of executable instructions for multi-format process control. For example, the integrated list of executable instructions may allow for a holistic NC program that interweaves executable instructions for additive manufacturing tasks, automated fiber placement tasks, or subtractive manufacturing tasks, without limitation, generated by independent software packages into an integrated list of executable instructions. By integrating separate lists of executable instructions generated by independent software packages, the integration software allows for the use of mature independent software packages without the need to independently develop custom software packages for creation of a list of executable instructions for a multi-format machine-driven process.

In accordance with this disclosure, a manufacturing tool system may use an integration software package to facilitate and coordinate the creation of two or more lists of executable instructions generated by two or more independent software packages and integrate the two or more lists of executable instructions into an integrated list of executable instructions to allow for a single list of executable instructions for multi-format control of a machine including two or more manufacturing tools (e.g., additive manufacturing tools, automated fiber placement tools, machining tools, etc.).

For example, the integration software package may have a comprehensive knowledge of a desired combined manufacturing process and the various requirements to execute the combined manufacturing process. This knowledge may allow the integration software to facilitate the communication of information passed back and forth between the two or more independent software packages via the integration software package or generated and provided by the integration software while the independent software packages are generating respective lists of executable instructions (e.g., list of executable instructions for additively manufacturing an article, subtractively manufacturing an article, etc.). This may allow for each respective list of executable instructions to be configured to be merged together into a single integrated list of executable instructions for performing a combined manufacturing process.

For instance, the integration software may provide design inputs (e.g., including three-dimensional representations of an article of manufacture) to a plurality of independent software packages where the design inputs relate to a pre-determined machine-driven process and are adapted by the integration software to be used by each independent software package. Each individual software package may then begin to generate one or more executable instructions such as, for example, instructions defining tool paths, material deposition, or material removal, without limitation. As a specific example, a software package configured to generate NC instructions for an additive manufacturing tool may generate a list of instructions for controlling a layer by layer deposition of a material to form an article based on the design inputs. While each individual software package is developing various executable instructions, each individual software package may communicate with the integration software package such that the integration software package may modify instructions generated in each individual software package, generate placeholder instructions, or generate additional instructions to be inserted into any of the generated lists of executable instructions based on the comprehensive knowledge of the integration software package of the combined manufacturing process such that the various lists of executable instructions generated at each of the independent software packages may be combined into a single list of executable instructions for use by a machine including a plurality of manufacturing tools (e.g., additive manufacturing tools, subtractive manufacturing tools, or automated fiber placement tools, without limitation).

Accordingly, because the integration software package allows for the creation of a single list of executable instructions using a plurality of disparate independent software packages the manufacturing tool system may enable the use of multiple manufacturing processes simultaneously while leveraging mature (e.g., already developed) software packages without having to produce a single software package capable of creating a list of executable instructions for a plurality of manufacturing processes from the ground up, which may be costly in both money and time. Moreover, the integration software package allows for far greater scalability compared to conventional approaches as new processes do not have to be hardcoded into an existing software package, further saving time and money that would otherwise be needed to develop such software.

Though discussed in the context of specific types of software packages (e.g., software packages used for generating NC instructions), the disclosure is not so limited. For example, the integration software discussed herein may be used with any type of independent software package that produces executable instructions for a process.

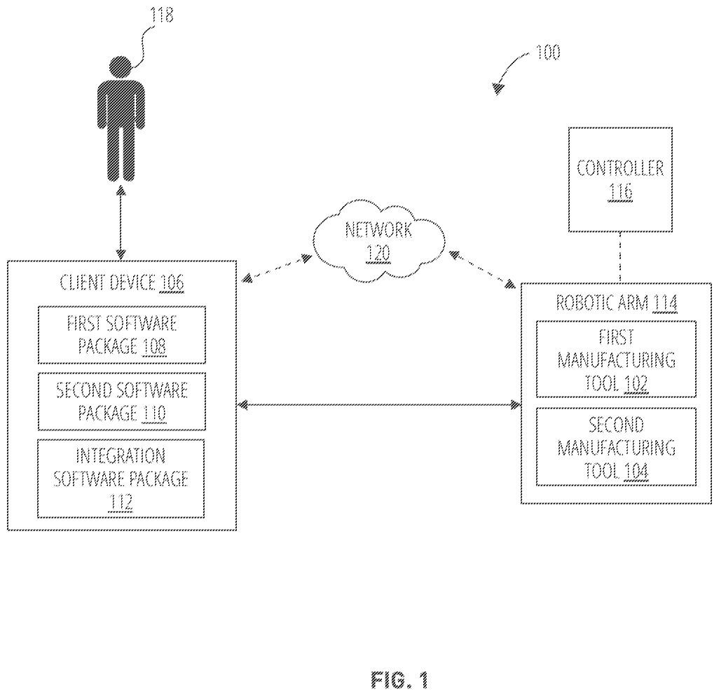

FIG. 1 illustrates a manufacturing tool system 100 according to one or more embodiments of the present disclosure. The manufacturing tool system 100 may include a client device 106 and a robotic arm 114. The client device may include a first software package 108, a second software package 110, and an integration software package 112. The robotic arm 114 may include a first manufacturing tool 102 and a second manufacturing tool 104. The robotic arm 114 may also include a controller 116. The client device 106 may represent various types of computing devices with which a user 118 may interact. For example, the client device 106 may be a non-mobile device (e.g., a desktop or server). In some embodiments, however, the client device 106 may be a mobile device (e.g., a cell phone, a smartphone, a PDA, a tablet, a laptop, a watch, a wearable device, etc.).

As illustrated in FIG. 1, the user 118 may interface with the manufacturing tool system 100 using the client device 106. For example, the user 118 may, via the client device 106, use the manufacturing tool system 100 to generate one or more executable instructions configured to control various operations of the robotic arm 114. The user 118 may be an individual (i.e., a human user), a business, a group, or any other entity. Although FIG. 1 illustrates only one user 118 associated with the client device 106, any number of (e.g., one or a plurality) of users may interact with (e.g., connect to and send and receive information to and from) the robotic arm 114 using a corresponding client device.

The first manufacturing tool 102 and the second manufacturing tool 104 may be different tools used for manufacturing an article. For example, the first manufacturing tool 102 or the second manufacturing tool 104 may be in the form of an additive manufacturing apparatus, an automated fiber placement apparatus, or a subtractive manufacturing apparatus, without limitation. Though the robotic arm 114 is shown and discussed having two manufacturing tools, the robotic arm 114 may include any number of manufacturing tools where each manufacturing tool may be configured to perform one or more processes for manufacturing or shaping an article of manufacture. Furthermore, each manufacturing tool may also be configured to perform a plurality of processes. For example, the first manufacturing tool 102 may be configured to perform both additive manufacturing and automated fiber placement.

The first software package 108, the second software package 110, and the integration software package 112 may be configured to produce one or more lists of executable instructions. For example, the first software package 108 may be configured to generate a list of executable NC instructions for controlling various operations of the robotic arm 114 and the first manufacturing tool 102 included on the robotic arm 114. As a specific non-limiting example, the first software package 108 may be configured to generate a list of NC instructions for additively manufacturing an article (e.g., by sequential layer deposition) and the first manufacturing tool 102 may include one or more components or tools for additive manufacturing such as feed material, and an extruder for depositing the feed material. The list of NC instructions generated by the first software package 108 may control various operations of the robotic arm 114 and the first manufacturing tool 102 to perform additive manufacturing. Additionally, as a non-limiting example, the second software package 110 may be configured to generate a list of NC instructions for machining (e.g., removing material) from an article and the second manufacturing tool 104 may include one or more machining components (e.g., machining tools for milling, turning, laser cutting, or water jet cutting, without limitation). The list of NC instructions generated by the second software package 110 may control various operations of the robotic arm 114 and the second manufacturing tool 104 to perform machining operations on an article.

The integration software package 112 may enable the user 118 to create a list of executable instructions responsive to merging the one or more lists of executable instructions generated at the first software package 108 or the second software package 110 where the integrated list of executable instructions may provide NC instructions for controlling the robotic arm 114, the first manufacturing tool 102, and the second manufacturing tool 104.

In some embodiments, the first software package 108, the second software package 110, and/or the integration software package 112 may be native applications installed on the client device 106. For example, the first software package 108, the second software package 110, and/or the integration software package 112 may be a desktop application that installs and runs on a desktop device. In some embodiments, the first software package 108, the second software package 110 and/or the integration software package may be a web application that may be executed via a web browser. Furthermore, in some embodiments, the integration software package 112 may be included as an extension or add-on to the first software package 108 or the second software package 110 (e.g., as an application plugin). For example, the first software package 108 may be a computer-aided design (CAD) software configured to design, simulate, and manufacture an article using additive manufacturing. The integration software package 112 may then be added to the first software package 108 as a plugin and facilitate communication between the first software package 108 and the second software package 110 (e.g., an automated fiber placement CAD software).

Though FIG. 1 shows the first software package 108, the second software package 110, and the integration software package 112 as all being included within client device 106, other arrangements are possible. For example, one or more of the first software package 108, the second software package 110, or the integration software package 112 may be included in one or more other devices in communication with the client device 106 such that each of the first software package 108 and the second software package 110 are able to communicate with (e.g., send and receive data to and from) the integration software package 112.

The client device 106 may be configured to send and receive data (e.g., one or more executable instructions) to and from the robotic arm 114. For example, the client device 106 and the robotic arm 114 may communicate directly via a wired connection (e.g., a wired local area network (LAN)) or a wireless local network (WLAN). The client device 106 and the robotic arm 114, however, may also communicate using a network 120. The network 120 may include one or more networks such as the Internet, and may use one or more communication platforms or technologies suitable for transmitting data and/or communication signals. In some embodiments, the client device 106 may communicate to the robotic arm 114 one or more executable instructions (e.g., a list NC instructions) for execution by the controller 116 where the one or more executable instructions are configured to control one or more operations of the robotic arm 114.

Though FIG. 1 depicts the numerically controlled device including a plurality of manufacturing tools as a robotic arm 114, any numerically controlled manufacturing equipment may be used. For example, the numerically controlled device may be in the form of a three-axis cartesian machine, a five-axis cartesian machine, a gantry machine, or a post (horizontal) machine, without limitation.

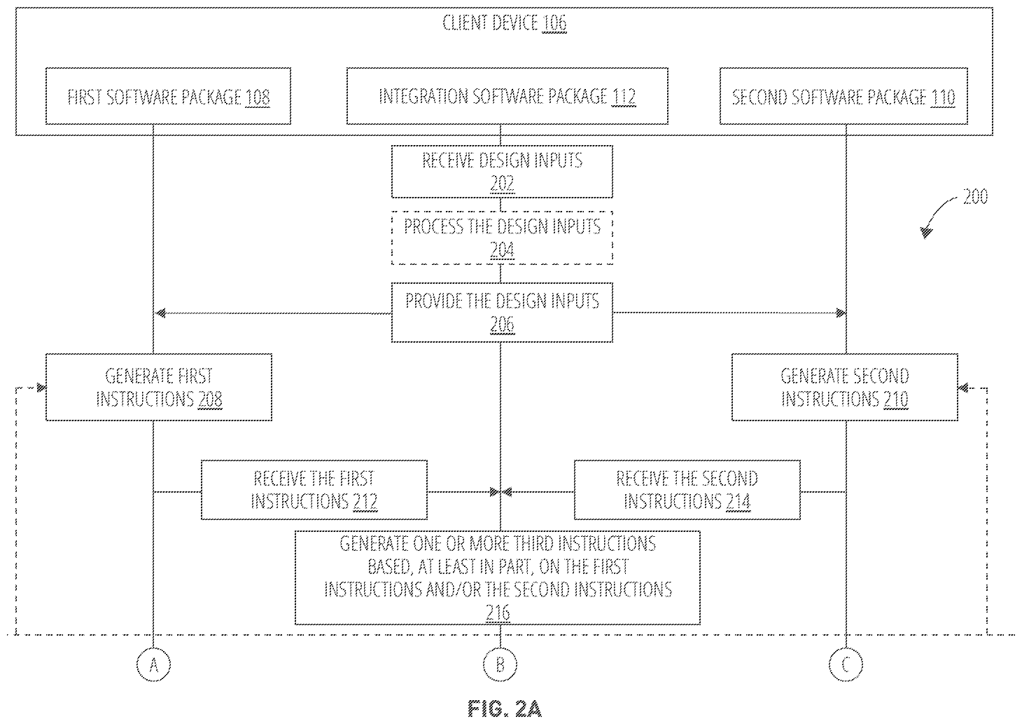

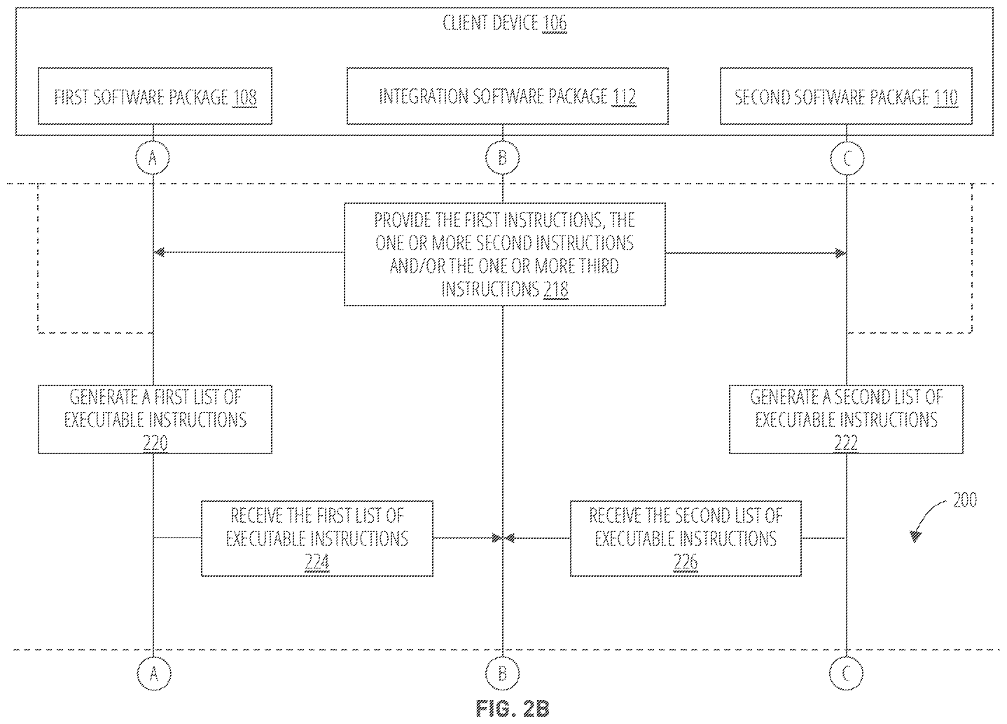

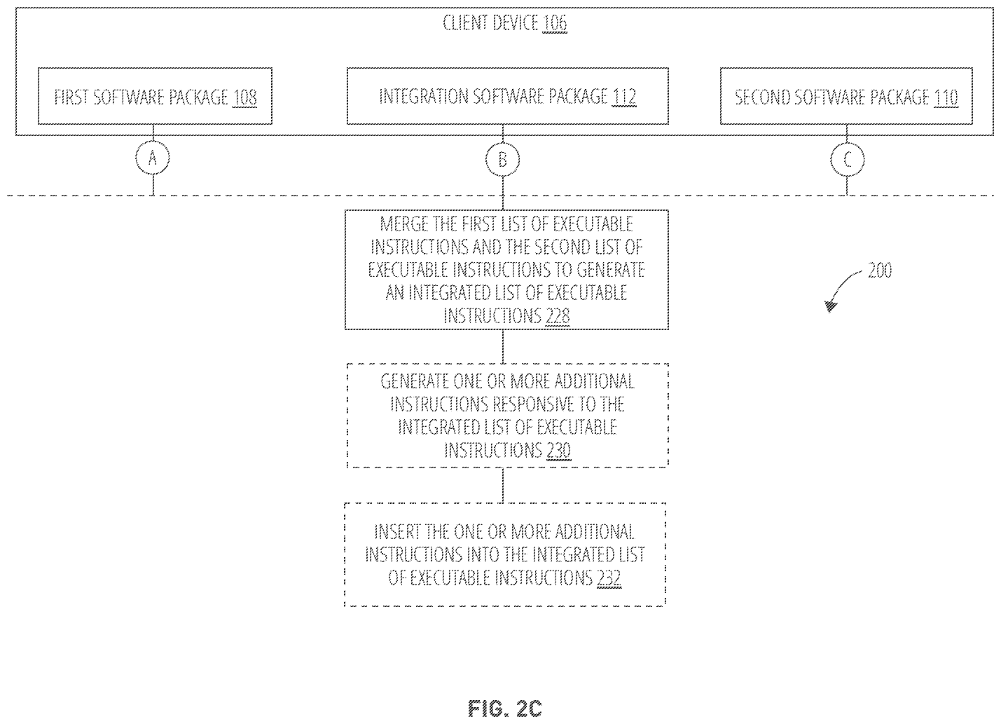

FIGS. 2A-2C illustrate a sequence-flow diagram 200 that a manufacturing tool system (e.g., the manufacturing tool system 100 of FIG. 1) may utilize to generate a list of one or more executable instructions for controlling a combined manufacturing process. The client device 106 including the first software package 108, the second software package 110, and the integration software package 112 shown in FIGS. 2A-2C may be as described with reference to FIG. 1.

Referring to the sequence-flow diagram 200, the integration software package 112 may receive design inputs for a predetermined machine-driven process, as shown in act 202. For example, the design inputs may include outputs from a CAD program such as three-dimensional representations of a desired article of manufacture, processing parameters or rules (e.g., movement speed, feed material, or temperatures, without limitation), defined geometric regions and regionalized processing parameters of the desired article of manufacture, constraint or tolerance specifications, or high level design criteria such as load or strength objectives or other performance criteria. The design inputs provided to the integration software package 112 may include data that allows the integration software package 112 to have a complete and comprehensive knowledge about how the independent manufacturing processes work, how each provided software package (e.g., the first software package 108 and the second software package 110) works as well as how each provided software package may work together to perform a combined machine-driven manufacturing process.

As shown in FIG. 2A, at act 204, the received design inputs may then be processed by the integration software package 112 to prepare the design inputs to be provided to each of the first software package 108 and the second software package 110. For example, the integration software package 112 may segment the design inputs and provide parts of the segmented data to the first software package 108 and the second software package 110 based on what the integration software knows about the combined process. As a specific, non-limiting example, the first software package 108 may be configured to generate tool paths (e.g., NC instructions) for an additive manufacturing process and the second software package 110 may generate tool paths for a machining manufacturing process. The integration software package 112 may provide the first software package 108 with design inputs to produce tool paths for manufacturing an article up until a machining step needs to take place to arrive at an article based on a combined manufacturing process between the first software package 108 and the second software package 110. Likewise, the integration software package 112 may provide design inputs to the second software package 110 to allow the second software package 110 to produce tool paths for machining an article that will be produced by the first software package 108 based on the design inputs provided to the first software package 108. In this way, the integration software package 112 may modify the design inputs to provide each first software package 108 with modified design inputs that are adapted to work with the first software package 108 or the second software package 110 (e.g., the data is adapted to work with the specific architecture of each software package). However, in some embodiments, the design inputs may be pre-prepared or be in a form such that processing the design inputs is not necessary. Accordingly, the design inputs may then be provided to the first software package 108 and the second software package 110, as shown in act 206. In some embodiments, the design inputs may be provided by a user (e.g., user 118) rather than or in addition to the integration software package 112.

Upon receiving the design inputs provided by the integration software package 112 (or user 118, as the case may be), the first software package 108 and/or the second software package 110 may generate one or more first executable instructions and/or one or more second executable instructions, respectively, as shown in acts 208 and 210. For example, referring again to the example where the first software package 108 is configured to produce tool paths and operations for additive manufacturing, the first software package 108 may, based on the design inputs provided by the integration software package 112, generate one or more first executable instructions (e.g., one or more tool paths and/or tool operations) for additively manufacturing an article (e.g., depositing layers of material) until the first software package 108 reaches a step that requires information from the integration software package 112 as to how to proceed. For example, the design inputs may contain a processing flag such that, when the first software package 108 reaches a certain point in generating executable instructions, the first software package 108 may then then cease to generate executable instructions. Furthermore, in some embodiments, the first software package 108 or the second software package 110 may generate respective executable instructions until they reach a point where the integration software package 112 knows, based on the combined process knowledge, that the first software package 108 or the second software package 110 needs additional information or data to proceed, such as at process flags included in the design inputs.

Additionally, the first software package 108 and/or the second software package 110 may generate intermediary or ancillary data in addition to executable instructions. For example, the first software package 108 or the second software package 110 may generate or modify data responsive to the design inputs while the first software package 108 or the second software package 110 is generating one or more executable instructions. The intermediary or ancillary data generated at the first software package 108 and/or the second software package 110 may include data that would be beneficial for use by other software packages. For example, intermediary or ancillary data generated at the first software package 108 may include data that may aid the second software package in generating instructions for a separate manufacturing process. As specific non-limiting examples, the intermediary or ancillary data may include geometric (e.g., CAD) data, manufacturing or producibility analysis data, region of interest data, layer data, processing parameters, information regarding processing conditions, or data defining unprocessed regions.

As shown in FIG. 2A, the integration software package 112 may receive one or more first executable instructions and/or one or more second executable instructions from the first software package 108 and the second software package 110, respectively, as shown in acts 212 and 214. Upon receiving the one or more first executable instructions and the one or more second executable instructions, the integration software package 112 may generate one or more third instructions based, at least in part, on the first instructions and/or the second instructions, as shown in act 216. For example, the integration software package 112 may evaluate and/or manipulate the one or more first executable instructions and the one or more second executable instructions as well as synthesize new data for use by the first software package 108 and/or the second software package 110 to generate additional instructions for performing a predetermined machine-driven process where the new data may be based on the one or more first executable instructions, the one or more second executable instructions and/or the comprehensive knowledge by the integration software package 112 of the combined predetermined machine-driven process. The evaluated, manipulated, or synthesized (e.g., generated) new data may be referred to herein as one or more third instructions.

In some embodiments, the third instructions may also include intermediary or ancillary data generated at the first software package 108 and/or the second software package 110. While intermediary or ancillary data may be partially represented in a finished list of executable instructions generated by the first software package 108 and/or the second software package 110, the intermediary or ancillary data may be more complete when generated while the first software package 108 or the second software package 110 is generating one or more executable instructions rather than potentially partial representations of the intermediary or ancillary data contained in a completed list of executable instructions generated by the first software package 108 or the second software package 110. As a specific non-limiting example, the integration software package 112 may analyze data (e.g., data including one or more instructions and intermediary or ancillary data) received from the first software package 108 and identify intermediary or ancillary data that would aid the second software package 110 in generating executable instructions. In some embodiments, this data may then be manipulated or adapted by the integration software package 112 for use by the second software package 110 or may be used by the integration software package 112 to synthesize or generate new data configured for use by the second software package 110.

Upon generating the one or more third instructions, the integration software package 112 may then provide the one or more first executable instructions, the one or more second executable instructions and/or the one or more third instructions to the first software package 108 and/or the second software package 110, as shown in act 218. For example, the integration software package 112 may have to manipulate the first executable instructions in order for them to be used by the second software package 110. As another example, upon receiving the one or more first executable instructions and the one or more second executable instructions from the first software package 108 and the second software package 110, respectively, the integration software package 112 may identify, based on a knowledge of the combined process, that the manufacturing process defined by the one or more first instructions will require one or more intermediary instructions from the one or more second executable instructions. In response, the integration software package 112 may generate one or more placeholder instructions or flags marking places within a process defined by the one or more first executable instructions where one or more of the second executable instructions will need to be placed. The placeholder instructions or flags may also contain an identification (ID) indicator associating each placeholder instruction or flag to one or more second executable instructions that may need to be injected at each flag or placeholder instruction. The various flags or placeholder instructions injected into the one or more first instructions and/or the one or more second instructions may enable the one or more first instructions and the one or more second instructions to be merged together. In some embodiments, the integration software package may provide the first executable instructions or second executable instructions without the third instructions. As a specific non-limiting example, the integration software package 112 may receive data from the first software package 108 and provide the data to the second software package 110 without manipulating the data or without generating or providing additional data, instructions, or flags.

The integration software package 112 may also provide to a software package (e.g., the first software package 108), based on the comprehensive combined process, data (including intermediary or ancillary data) generated at a different software package (e.g., the second software package 110) to enable the software package to generate instructions in accordance with the combined process. As a specific, non-limiting example where the first software package 108 is configured to generate one or more executable instructions for additive manufacturing and the second software package 110 is configured to generate one or more executable instructions for machining (e.g., removing material from) an article, the first software package 108 may generate instructions that are configured to generate a partially formed article of manufacture responsive to the design inputs. These design inputs may have also been provided to the second software package 110 to generate one or more machining instructions to be performed on a partially formed article (e.g., an article that will be formed through execution of the instructions generated by the first software package 108). The second software package 110 may then generate one or more instructions (e.g., tool paths) to remove material from the article that would be formed by the instructions generated by the first software package 108. The new simulated geometry that would result from the machining instructions may then be provided to the integration software package 112 which may then communicate the simulated geometry to the first software package 108 so that the first software package 108 may generate additional additive manufacturing instructions (e.g., instructions for layer deposition) taking into account the new simulated geometry that would result from execution of the machining instructions generated by the second software package 110.

As another non-limiting example, the second software package 110 may be configured to perform automated fiber placement instead of machining. The second software package 110 may generate one or more executable instructions (e.g., tool paths and various manufacturing tool operations such as fiber deposition) given the design inputs to generate at least part of an article using automated fiber placement. The resulting simulated geometry may then be communicated to the integration software package 112 which may then communicate it to the first software package 108. The first software package 108 may then generate one or more instructions based on the provided simulated geometry. For example, the one or more instructions generated by the first software package 108 may be configured to perform additive manufacturing processes (e.g., tool paths and material deposition) for filling in small areas that may be difficult to fill using automated fiber placement.

The first software package 108, the second software package 110, and the integration software package may then repeat acts 208, 210, 212, 214, 216, or 218 as many times as necessary until the first software package 108 and the second software package 110 are able to generate a completed list of executable instructions for their respective manufacturing processes. For example, after the integration software package 112 provides the first executable instructions, the second executable instructions, or the third instructions to the first software package 108 or the second software package 110, the first software package 108 or the second software package 110 may then generate additional instructions based on the instructions provided by the integration software. These additional instructions may then be communicated to the integration software package 112, which may evaluate or modify the additional instructions or generate new instructions based on the additional instructions and then provide the new instructions to the first software package 108 and second software package 110, and so on.

The first software package 108 and the second software package 110 may then generate a first list of executable instructions and a second list of executable instructions, respectively, as shown in acts 220 and 222. The first list of executable instructions and the second list of executable instructions may each define a single manufacturing process (e.g., the first list representative of an additive manufacturing process and the second representative of a machining manufacturing process). The integration software may then receive the first list of executable instructions and the second list of executable instructions, as shown in acts 224 and 226. Furthermore, because the integration software package 112 has coordinated the creation of each of the first list of executable instructions and the second list of executable instructions, each list of executable instructions may be configured to be merged together to form a single list of executable instructions.

Upon receiving the first list of executable instructions and the second list of executable instructions, the integration software package 112 may merge the first list of executable instructions and the second list of executable instructions to generate an integrated list of executable instructions, as shown in act 228. For example, the integration software package 112 may replace placeholder instructions or flags within one or each of the first list of executable instructions and the second list of executable instructions with corresponding instructions in each of the first list of executable instructions or the second list of executable instructions. For example, each placeholder flag in the first list of executable instructions may have an ID indicator corresponding to an instruction within the second list of executable instructions. The integration software package 112 may then replace each flag or placeholder instruction with its corresponding instruction in the second list of executable instructions. Furthermore, the integration software may merge the first list of executable instructions and the second list of executable instructions such that the integrated list of executable instructions has an ordering configured to perform a combined machine-driven process according to the knowledge of the integration software package 112 of the comprehensive combined machine-driven process. For example, in a process involving layer deposition using additive manufacturing and automated fiber placement, a process may involve requiring switching between the additive manufacturing process and the automated fiber placement process a plurality of times within a single deposition layer of an article. The integration software package 112, the only entity with a combined knowledge of the fiber placement and the additive manufacturing processes, may order (e.g., interweave) tool path instructions from each of the first list of executable instructions and the second list of executable instructions to be able to efficiently deposit the layer requiring both additive manufacturing and automated fiber placement.

For example, an additive manufacturing tool path may involve continuously depositing material along a longitudinal axis of an article where there is a gap in the tool path where an automated fiber placement section is designed to be. Similarly, an automated fiber placement tool path may involve depositing fiber material along the same longitudinal axis within the gap. The integration software package 112 may order the tool paths from both the additive manufacturing process (e.g., the first list of executable instructions) and the automated fiber placement process (e.g., the second list of executable instructions) to allow a manufacturing tool to begin depositing material according to the additive manufacturing tool path until reaching the gap, switching to an automated fiber placement tool, performing fiber placement in the same longitudinal direction, and then switch back to additive manufacturing where the gap ends and continue to a distal end of the article (e.g., the end of the longitudinal length of the article for that deposition layer).

In some embodiments, the integration software package 112 may generate one or more additional instructions responsive to the integrated list of executable instructions, as shown in act 230. For example, the integration software package 112 may generate additional NC instructions based on the knowledge of the integration software package 112 of the comprehensive combined process. The integration software package 112 may know that one or more transitionary instructions need to be added between, for example, instructions from the first list of executable instructions and instructions from the second list of executable instructions to successfully perform the process. As a specific, non-limiting example, the integration software package 112 may know that transition instructions to move a tool into the correct position or to prepare a tool (e.g., preheat a heating element for material deposition) is needed to perform the combined manufacturing process. The integration software package 112 may then generate the appropriate instruction and insert the instruction into the integrated list of executable instructions at the appropriate location, as shown in act 232.

In some embodiments, the integration software package 112 does not need to generate the additional instructions but rather may have access to a database of pre-defined executable instructions that are known to be needed for performing a variety of machine-driven processes including transitionary instructions. The integration software package 112 may then select the appropriate pre-defined executable instructions and insert them into the integrated list of executable instructions.

Accordingly, the ability to facilitate the creation of manufacturing processes to combine them into a single process allows fully mature software packages already developed to produce lists of executable instructions that may be merged with other NC process lists to form a single list of executable instructions for performing a combined process utilizing a plurality of different manufacturing tools without the need for developing complicated multi-process generation software. Though discussed herein with respect to a first software package and a software package, the systems, processes, and methods discussed herein may incorporate more than two software packages. For example, the various systems, methods, and processes discussed herein may be scalable so as to facilitate any number of software packages so long as design inputs may be distributed to two or more software packages and two or more lists of executable instructions are received from the two or more software packages such that the two or more lists of executable instructions may be merged as described above.

In some embodiments, the integration software package 112 may then perform one or more simulations using the integrated list of executable instructions. For example, the integration software package 112 may run computer simulations simulating the operation of a manufacturing tool executing the integrated list of executable instructions. In some embodiments, the integration software package 112 may then modify the integrated list of executable instructions responsive to the simulations. For example, if the simulations reveal a problem in the combined manufacturing process, the integration software package 112 may identify the problem and generate, obtain, or modify one or more executable instructions to address the identified problem and then run subsequent simulations implementing the generated, obtained, or modified instructions. This process may be repeated until the combined process is successfully simulated.

Furthermore, in some embodiments, the user 118 may, via the client device 106, modify one or more instructions within the integrated list of executable instructions or generate custom instructions and insert the custom instructions into the integrated list of executable instructions. For example, the integration software package 112, the first software package 108, or the second software package 110 may generate a GUI showing the integrated list of executable instructions and present the GUI to the user 118 via a display of the client device 106. The user 118 may then use an input device (e.g., mouse and/or keyboard) to edit, reorder, or add instructions within the integrated list of executable instructions.

In some embodiments, the integration software package 112 may automatically reorder the integrated list of executable instructions responsive to the user 118 making one or more changes to the integrated list of executable instructions. Furthermore, the integration software package 112 may also generate one or more recommendations for the user 118 to make one or more changes to the list of executable instructions based on the comprehensive knowledge of the combined process. For example, the integration software package 112 may recognize that a certain instruction is needed within the integrated list of generated instructions but is unable to generate or obtain such an instruction. The integration software package 112 may then present via a GUI shown on the display of the client device 106 the recommended action to modify the integrated list of executable instructions in order to fill in the needed instruction.

After the integrated list of executable instructions has been generated, the integration software package 112 may generate one or more data packages including the integrated list of executable instructions. The integration software package 112 may then, via the client device 106, send the one or more data packages to a manufacturing tool (e.g., the robotic arm 114). The manufacturing tool may then form an article based, at least in part, on the integrated list of executable instructions responsive to receiving the one or more data packages.

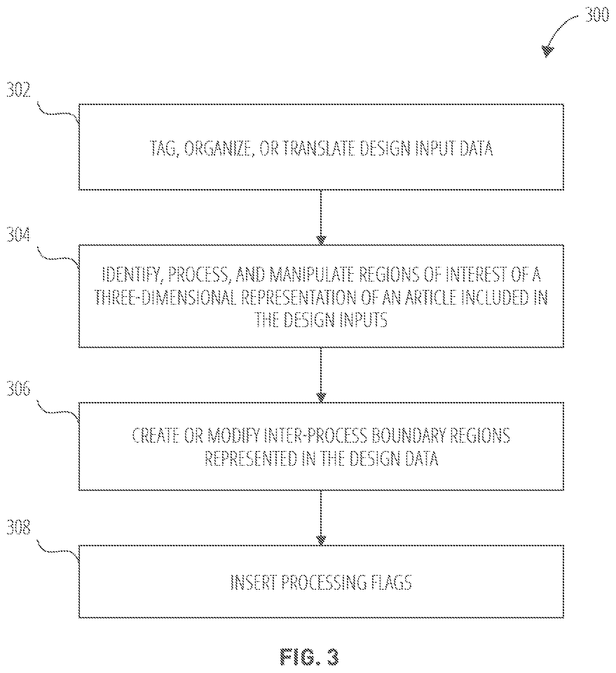

FIG. 3 is a flowchart 300 illustrating an example operation of a manufacturing tool system (e.g., the manufacturing tool system 100 of FIG. 1) performed by a processor executing instructions stored on a computer-readable storage medium. For instance, FIG. 3 shows one or more embodiments of a sequence flow diagram that the manufacturing tool system 100 may utilize to process one or more design inputs for a machine-driven process. At operation 302, the manufacturing tool system 100 tags, organizes, or translates design input data. For example, the manufacturing tool system 100 may, via the integration software package 112, may tag, organize or translate data to make the data readable or usable to each separate software package (e.g., first software package 108 and second software package 110). At operation 304, the manufacturing tool system 100 may identify regions of interest within the design data (e.g., regions where they may exist a transition between different manufacturing processes) and manipulate the identified regions for processing by each software package (e.g., preparing new metadata that it will use in the identified transition region). At operation 306, the manufacturing tool system 100 may create boundary regions that don't exist within the design data that may be needed to perform a combined manufacturing process as well as modify existing boundaries (e.g., inter-process boundaries between disparate manufacturing processes). At operation 308, the manufacturing tool system 100 may insert flags that will be needed later on by any one of a plurality of independent software packages as the independent software packages generate respective lists of executable instructions for disparate manufacturing processes. For example, the flags may be inserted at different points within the design data to indicate that a certain process or instruction will need to be executed in the manufacturing process.

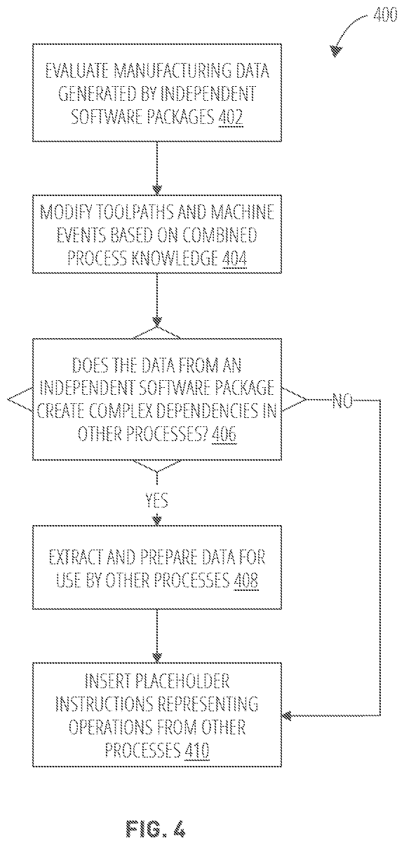

FIG. 4 is a flowchart 400 illustrating an example operation of a manufacturing tool system (e.g., the manufacturing tool system 100 of FIG. 1) performed by a processor executing instructions stored on a computer-readable storage medium. For instance, FIG. 4 shows one or more embodiments of a sequence flow diagram that the manufacturing tool system 100 may utilize to evaluate or manipulate data received from independent software packages (e.g., the first software package 108 and the second software package 110) while the independent software packages are generating one or more executable instructions for performing a manufacturing process. At operation 402, the manufacturing tool system 100 may evaluate manufacturing data generated by independent software packages (e.g., the first software package 108 and the second software package 110). At operation 404, the manufacturing tool system 100 may modify tool paths and machine events (e.g., defined by one or more executable instructions) based on a combined process knowledge. For example, the integration software package 112 may be the only entity in the manufacturing tool system 100 that has a comprehensive knowledge of each of a plurality of manufacturing processes that will be used via robotic arm 114 to manufacture an article. Based on this combined process knowledge, the integration software package 112 may modify tool paths of generated by one independent software package based on what it knows will be necessary in order to insert or integrate one or more tool paths from another independent software package.

At operation 406, the manufacturing tool system 100 may check whether the data from an independent software package creates complex dependencies in other processes. For example, an independent software package (e.g., a software package configured to generate executable instructions for machining an article) may generate instructions that will alter the geometry of an article to be manufactured. The integration software package 112 may identify that this alteration of the geometry will require that one or more other independent software packages may require knowledge of this change in geometry in order to accurately generate the tool paths or machine events for the combined manufacturing process. If such a dependency is not identified by the integration software package 112, then the flowchart 400 may proceed to operation 410. If such a dependency is identified, then the flowchart 400 may proceed to operation 408.

At operation 408, the manufacturing tool system 100 may extract the dependency identified in operation 406 and prepare (e.g., manipulate or adapt) the data for use by other independent software packages. At operation 410, the manufacturing tool system 100 may insert placeholder instructions representing operations from other manufacturing processes (e.g., generated from other independent software packages).

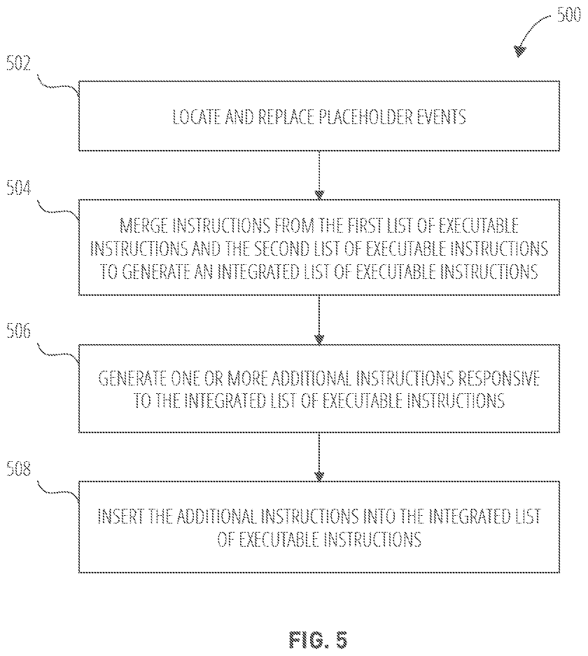

FIG. 5 is a flowchart 500 illustrating an example operation of a manufacturing tool system (e.g., the manufacturing tool system 100 of FIG. 1) performed by a processor executing instructions stored on a computer-readable storage medium. For instance, FIG. 5 shows one or more embodiments of a sequence flow diagram that the manufacturing tool system 100 may utilize to merge independent lists of executable instructions received from independent software packages (e.g., the first software package 108 and the second software package 110) into an integrated list of executable instructions configured to be used by the robotic arm 114. At operation 502, the manufacturing tool system 100 may locate and replace placeholder events in each received list of executable instructions. For example, the manufacturing tool system 100 may, via the integration software package 112, identify placeholder instructions or flags that have been inserted into each list of executable instructions and identify a corresponding instruction in another of the lists of executable instructions that the placeholder will need to be replaced by. For example, each placeholder instruction or flag may include an identification indicator that associates that instruction or flag with an executable instruction in a list of the lists of executable instructions received from the independent software packages.

At operation 504, the manufacturing tool system 100 may merge instructions from the different lists of executable instructions (e.g., a first list of executable instructions received from the first software package 108 and a second list of executable instructions received from the second software package 110) to generate an integrated list of executable instructions. For example, the manufacturing tool system 100 may, via the integration software package 112, replace each placeholder instruction or flag within one or more lists of executable instructions with the corresponding instruction in others of the lists of executable instructions. After each placeholder instruction or flag has been replaced, the various lists may then be combined and ordered by the integration software package 112 to generate an integrated list of executable instructions configured to perform a combined manufacturing process. At operation 506, the manufacturing tool system 100 may generate one or more additional instructions responsive to the integrated list of executable instructions. For example, the integration software package 112 may identify executable instructions that may not be tied to any one manufacturing process but may be necessary for the combined manufacturing process and then generate the required instruction. As a specific, non-limiting example, the integration software package 112 may generate transitionary instructions for transitioning (e.g., positioning tools for changing from one process to another process) between different processes of the combined manufacturing process. At operation 508, the manufacturing tool system 100 may, via the integration software package 112, insert the additional instructions into the integrated list of executable instructions.

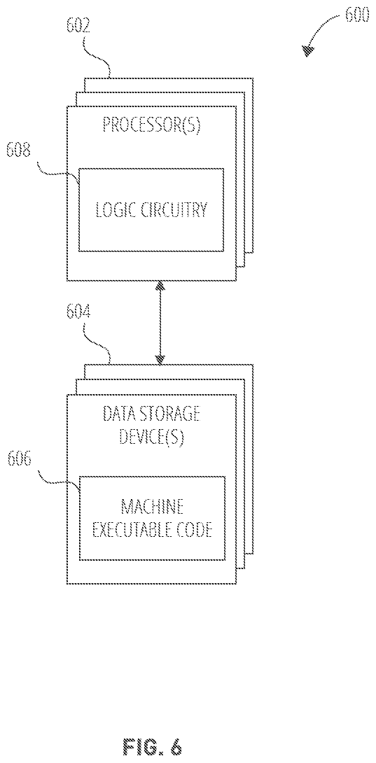

It will be appreciated by those of ordinary skill in the art that functional elements of examples disclosed herein (e.g., functions, operations, acts, processes, and/or methods) may be implemented in any suitable hardware, software, firmware, or combinations thereof. FIG. 6 illustrates non-limiting examples of implementations of functional elements disclosed herein. In some examples, some or all portions of the functional elements disclosed herein may be performed by hardware specially configured for carrying out the functional elements.

FIG. 6 is a block diagram of circuitry 600 that, in some examples, may be used to implement various functions, operations, acts, processes, and/or methods disclosed herein. The circuitry 600 includes one or more processors 606 (sometimes referred to herein as “processors 606”) operably coupled to one or more data storage devices 608 (sometimes referred to herein as “storage 608”). The storage 608 includes machine executable code 610 stored thereon and the processors 606 include logic circuitry 612. The machine executable code 610 includes information describing functional elements that may be implemented by (e.g., performed by) the logic circuitry 612. The logic circuitry 612 is adapted to implement (e.g., perform) the functional elements described by the machine executable code 610. The circuitry 600, when executing the functional elements described by the machine executable code 610, should be considered as special purpose hardware configured for carrying out functional elements disclosed herein. In some examples, the processors 606 may perform the functional elements described by the machine executable code 610 sequentially, concurrently (e.g., on one or more different hardware platforms), or in one or more parallel process streams.

When implemented by the logic circuitry 612 of the processors 606, the machine executable code 610 is to adapt the processors 606 to perform operations of examples disclosed herein. For example, the machine executable code 610 may adapt the processors 606 to perform at least a portion or a totality of the sequence-flow diagram 200 of FIGS. 2A-2C. Additionally, the machine executable code 610 may adapt the processors 606 to perform at least a portion or the totality of the flowcharts 300 of FIG. 3, 400 of FIG. 4, or 500 of FIG. 5.

The processors 606 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer executes functional elements corresponding to the machine executable code 610 (e.g., software code, firmware code, hardware descriptions) related to examples of the present disclosure. It is noted that a general-purpose processor (may also be referred to herein as a host processor or simply a host) may be a microprocessor, but in the alternative, the processors 606 may include any conventional processor, controller, microcontroller, or state machine. The processors 606 may also be implemented as a combination of computing devices, such as a combination of a DSP and a microprocessor, a plurality of microprocessors, one or more microprocessors in conjunction with a DSP core, or any other such configuration.

In some examples, the storage 608 includes volatile data storage (e.g., random-access memory (RAM)), non-volatile data storage (e.g., Flash memory, a hard disc drive, a solid state drive, erasable programmable read-only memory (EPROM), etc.). In some examples, the processors 606 and the storage 608 may be implemented into a single device (e.g., a semiconductor device product, a system on chip (SOC), etc.). In some examples, the processors 606 and the storage 608 may be implemented into separate devices.

In some examples, the machine executable code 610 may include computer-readable instructions (e.g., software code, firmware code). By way of non-limiting example, the computer-readable instructions may be stored by the storage 608, accessed directly by the processors 606, and executed by the processors 606 using at least the logic circuitry 612. Also by way of non-limiting example, the computer-readable instructions may be stored on the storage 608, transferred to a memory device (not shown) for execution, and executed by the processors 606 using at least the logic circuitry 612. Accordingly, in some examples, the logic circuitry 612 includes electrically configurable logic circuitry.

In some examples, the machine executable code 610 may describe hardware (e.g., circuitry) to be implemented in the logic circuitry 612 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, VERILOG™, SYSTEMVERILOG™ or very large scale integration (VLSI) hardware description language (VHDL™) may be used.

HDL descriptions may be converted into descriptions at any of numerous other levels of abstraction as desired. As a non-limiting example, a high-level description may be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuitry 612 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples, the machine executable code 610 may include an HDL, an RTL, a GL description, a mask level description, other hardware description, or any combination thereof.

In examples where the machine executable code 610 includes a hardware description (at any level of abstraction), a system (not shown, but including the storage 608) may implement the hardware description described by the machine executable code 610. By way of non-limiting example, the processors 606 may include a programmable logic device (e.g., an FPGA or a PLC) and the logic circuitry 612 may be electrically controlled to implement circuitry corresponding to the hardware description into the logic circuitry 612. Also by way of non-limiting example, the logic circuitry 612 may include hard-wired logic manufactured by a manufacturing system (not shown, but including the storage 608) according to the hardware description of the machine executable code 610.

Regardless of whether the machine executable code 610 includes computer-readable instructions or a hardware description, the logic circuitry 612 is adapted to perform the functional elements described by the machine executable code 610 when implementing the functional elements of the machine executable code 610. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, etc.) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

The illustrations presented herein are not meant to be actual views of any particular method, system, device, or structure, but are merely idealized representations that are employed to describe the examples. In some instances, similar structures or components in the various drawings may retain the same or similar numbering for the convenience of the reader; however, the similarity in numbering does not necessarily mean that the structures or components are identical in size, composition, configuration, or any other property.

The foregoing description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example of this disclosure to the specified components, steps, features, functions, or the like.

It will be readily understood that the components of the examples as generally described herein and illustrated in the drawings could be arranged and designed in a wide variety of different configurations. Thus, the following description of various examples is not intended to limit the scope, but is merely representative of various examples. While the various aspects of the examples may be presented in the drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding and are within the abilities of persons of ordinary skill in the relevant art.

Those of ordinary skill in the art will understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logic, blocks, modules, and circuits described in connection with the examples disclosed herein may be implemented or performed with a general purpose processor, a special purpose processor, a digital signal processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is to execute computing instructions (e.g., software code) related to examples.

The examples herein may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, other structure, or combinations thereof. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.,” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may include one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. A method comprising:
receiving design inputs for a pre-determined machine-driven process;
providing the design inputs to a first software package and a second software package, each of the first software package and the second software package configured to generate a list of executable instructions for performing at least a portion of the pre-determined machine-driven process;
receiving one or more first instructions from the first software package and one or more second instructions from the second software package;
generating one or more third instructions based, at least in part, on the one or more first instructions or the one or more second instructions;
providing at least one of the one or more first instructions, the one or more second instructions, and the one or more third instructions to the first software package and/or the second software package;
receiving a first list of executable instructions and a second list of executable instructions from the first software package and the second software package, respectively; and
merging the first list of executable instructions and the second list of executable instructions to generate an integrated list of executable instructions.

2. The method of claim 1, further comprising:
modifying the design inputs for use by the first software package and/or the second software package;
creating or modifying three-dimensional regions of a three-dimensional representation of an article of manufacture included in the design inputs; and
inserting process indicators based on the pre-determined machine-driven process into the design inputs.

3. The method of claim 1, further comprising:
generating one or more additional instructions responsive to the integrated list of executable instructions; and
inserting the one or more additional instructions into the integrated list of executable instructions.

4. The method of claim 1, further comprising:
generating one or more data packages including the integrated list of executable instructions;
receiving, at a manufacturing tool, the one or more data packages; and
forming an article via the manufacturing tool based, at least in part, on the integrated list of executable instructions responsive to receiving the one or more data packages.

5. The method of claim 4, wherein the manufacturing tool comprises a robotic arm configured to perform one or more of additive manufacturing, automated fiber placement, or subtractive manufacturing.

6. The method of claim 1, wherein generating the one or more third instructions includes modifying the one or more first instructions and/or the one or more second instructions.

7. The method of claim 1, wherein the design inputs include a three-dimensional representation of an article.

8. The method of claim 1, wherein the one or more third instructions include one or more placeholder instructions or one or more process indicators.

9. The method of claim 8, wherein merging the first list of executable instructions and the second list of executable instructions comprises replacing placeholder instructions included in the first list of executable instructions with one or more instructions of the second list of executable instructions.

10. The method of claim 8, wherein merging the first list of executable instructions and the second list of executable instructions comprises replacing the one or more placeholder instructions included in the first list of executable instructions or the second list of executable instructions with one or more instructions from the other of the first list of executable instructions or the second list of executable instructions or one or more additional instruction.

11. The method of claim 1, further comprising simulating the integrated list of executable instructions.

12. The method of claim 1, further comprising presenting for display on a client device, the integrated list of executable instructions.

13. The method of claim 1, further comprising generating one or more recommended changes to the integrated list of executable instructions based, at least in part, on the pre-determined machine-driven process.

14. A system comprising:
a numerically controlled device comprising a plurality of manufacturing tools;
at least one processor; and
at least one non-transitory computer-readable storage medium storing instructions that, when executed by the at least one processor, cause the system to:
receive design inputs for manufacturing an article;
provide the design inputs to a first software package and a second software package, each of the first software package and the second software package configured to generate a list of executable instructions configured to perform at least part of a process of manufacturing the article;
receive one or more first instructions from the first software package and one or more second instructions from the second software package;
generate one or more third instructions based, at least in part, on the one or more first instructions or the one or more second instructions;
provide the one or more first instructions, the one or more second instructions, and/or the one or more third instructions to the first software package and/or the second software package;
receive a first list of executable instructions and a second list of executable instructions from the first software package and the second software package, respectively; and
merge the first list of executable instructions and the second list of executable instructions to generate an integrated list of executable instructions.

15. The system of claim 14, wherein the plurality of manufacturing tools comprise an additive manufacturing tool, an automated fiber placement tool, and a subtractive manufacturing tool.

16. The system of claim 14, wherein generating one or more third instructions includes modifying one or more tool paths generated at the first software package or the second software package.

17. The system of claim 14, wherein the one or more third instructions include one or more placeholder instructions.

18. The system of claim 14, wherein the instructions stored on the at least one non-transitory computer-readable storage medium, when executed by the at least one processor, cause the system to:
automatically generate one or more transition instructions responsive to the integrated list of executable instructions; and
insert the one or more transition instructions into the integrated list of executable instructions.

19. The system of claim 18, wherein the instructions stored on the at least one non-transitory computer-readable storage medium, when executed by the at least one processor, cause the system to:
reorder the integrated list of executable instructions responsive to a user editing one or more instructions of the integrated list of executable instructions.

20. A non-transitory computer-readable storage medium storing instructions thereon that, when executed by at least one processor, cause the at least on processor to perform acts comprising:
receiving design inputs for a pre-determined machine-driven process;
providing the design inputs to a first software package and a second software package, each of the first software package and the second software package configured to generate a list of executable instructions for performing at least a portion of the pre-determined machine-driven process;
receiving one or more first instructions from the first software package and one or more second instructions from the second software package;
generating one or more third instructions based, at least in part, on the one or more first instructions or the one or more second instructions;
providing the one or more first instructions, the one or more second instructions, and/or the one or more third instructions to the first software package and/or the second software package;
receiving a first list of executable instructions and a second list of executable instructions from the first software package and the second software package, respectively; and
merging the first list of executable instructions and the second list of executable instructions to generate an integrated list of executable instructions.
